(19) United States
(12) Patent Application Publication
(10) Pub. No.: US 2025/0185234 A1
(43) Pub. Date: Jun. 5, 2025

(54) SEMICONDUCTOR DEVICE WITH ASSISTANCE FEATURES AND METHOD FOR FABRICATING THE SAME

(71) Applicant: NANYA TECHNOLOGY CORPORATION, NEW TAIPEI CITY (TW)

(72) Inventor: TSE-YAO HUANG, TAIPEI CITY (TW)

(21) Appl. No.: 19/048,372

(22) Filed: Feb. 7, 2025

Related U.S. Application Data
(63) Continuation of application No. 17/978,336, filed on Nov. 1, 2022.

(51) Int. Cl. H10B 12/00

(52) U.S. Cl. CPC H10B 12/485; H10B 12/34

(57) ABSTRACT

The present application discloses a semiconductor device and a method for fabricating the semiconductor device. The semiconductor device includes a substrate; a first contact positioned on the substrate; a first assistance feature including: a bottom portion positioned in the first contact, and a capping portion positioned on the bottom portion and on a top surface of the first contact; a second contact positioned on the substrate and separated from the first contact; and a second assistance feature positioned on the second contact. The first assistance feature and the second assistance feature include germanium or silicon germanium.

### CROSS-REFERENCE TO RELATED APPLICATION

This application is a continuation application of U.S. Non-Provisional application Ser. No. 17/978,336 filed Nov. 1, 2022, which is incorporated herein by reference in its entirety.

### TECHNICAL FIELD

The present disclosure relates to a semiconductor device and a method for fabricating the semiconductor device, and more particularly, to a semiconductor device with assistance features and a method for fabricating the semiconductor device with the assistance features.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a first contact positioned on the substrate; a first assistance feature including: a bottom portion positioned in the first contact, and a capping portion positioned on the bottom portion and on a top surface of the first contact; a second contact positioned on the substrate and separated from the first contact; and a second assistance feature positioned on the second contact. The first assistance feature and the second assistance feature include germanium or silicon germanium.

Another aspect of the present disclosure provides a semiconductor device including a substrate; a plurality of impurity regions positioned in the substrate and separated from each other; a word line structure positioned between the plurality of impurity regions and positioned in the substrate; a first contact and a second contact respectively and correspondingly positioned on the plurality of impurity regions; and a first assistance feature including: a bottom portion positioned in the first contact, and a capping portion positioned on the bottom portion and on a top surface of the first contact. The first assistance feature and the second assistance feature include germanium or silicon germanium.

Another aspect of the present disclosure provides a method for fabricating a semiconductor device including providing a substrate; forming a first dielectric layer on the substrate; forming a first opening and a second opening along the first dielectric layer; forming a layer of conductive material to partially fill the first opening, fill the second opening, and cover a top surface of the first dielectric layer; performing a planarization process until the top surface of the first dielectric layer is exposed to turn the layer of conductive material into a first contact in the first opening and a second contact in the second opening; and forming a first assistance feature on the first contact and forming a second assistance feature on the second contact. The first assistance feature and the second assistance feature include germanium or silicon germanium.

Due to the design of the semiconductor device of the present disclosure, the contact resistance of the first contact and the second contact may be reduced by employing the first assistance feature and the second assistance feature. As a result, the performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 6 illustrate, in schematic cross-sectional view diagrams, a flow for fabricating the semiconductor device in accordance with one embodiment of the present disclosure; and

FIGS. 7 to 13 illustrate, in schematic cross-sectional view diagrams, semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

It should be noted that, in the description of the present disclosure, a surface of an element (or a feature) located at the highest vertical level along the dimension Z is referred to as a top surface of the element (or the feature). A surface of an element (or a feature) located at the lowest vertical level along the dimension Z is referred to as a bottom surface of the element (or the feature).

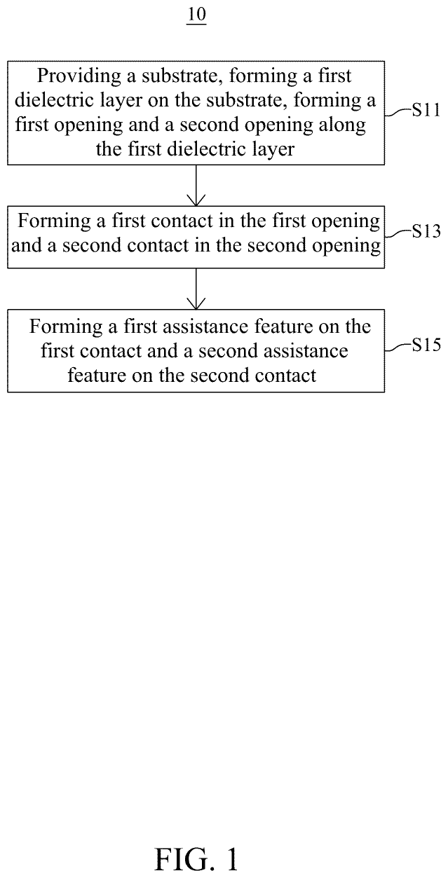

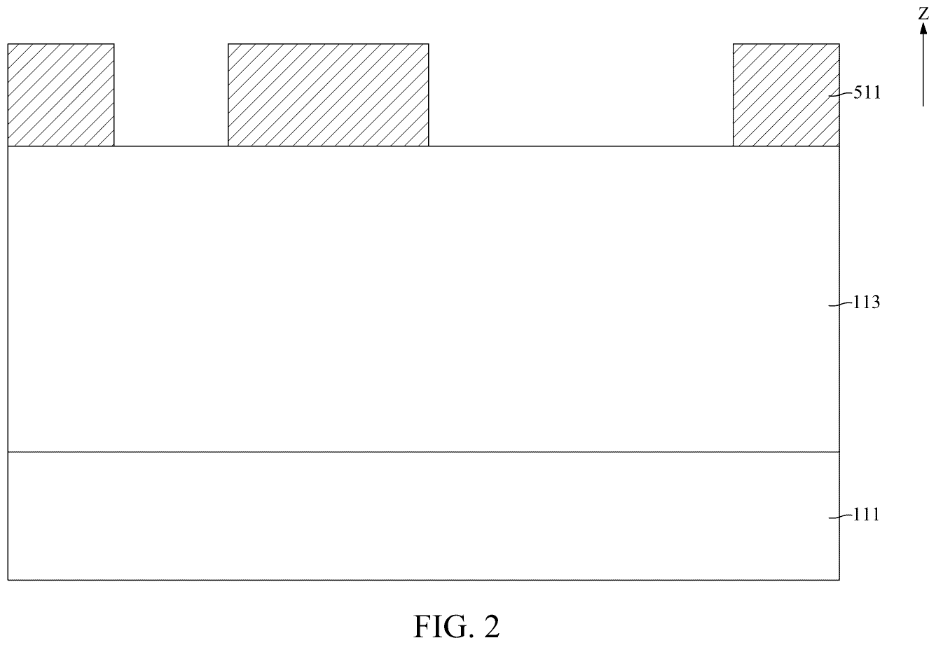

FIG. 1 illustrates, in a flowchart diagram form, a method 10 for fabricating a semiconductor device 1A in accordance with one embodiment of the present disclosure. FIGS. 2 to 6 illustrate, in schematic cross-sectional view diagrams, a flow for fabricating the semiconductor device 1A in accordance with one embodiment of the present disclosure.

With reference to FIGS. 1 to 3, at step S11, a substrate 111 may be provided, a first dielectric layer 113 may be formed on the substrate 111, a first opening 513 and a second opening 515 may be formed along the first dielectric layer 113.

With reference to FIG. 2, in some embodiments, the substrate 111 may include a bulk semiconductor substrate that is composed entirely of at least one semiconductor material, a plurality of device elements (not shown for clarity), a plurality of dielectric layers (not shown for clarity), and a plurality of conductive features (not shown for clarity). The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 111 may further include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and 200 nm.

It should be noted that, in the description of present disclosure, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

The plurality of device elements may be formed on the substrate 111. Some portions of the plurality of device elements may be formed in the substrate 111. The plurality of device elements may be transistors such as complementary metal-oxide-semiconductor transistors, metal-oxide-semiconductor field-effect transistors, fin field-effect-transistors, the like, or a combination thereof.

The plurality of dielectric layers may be formed on the substrate 111 and cover the plurality of device elements. In some embodiments, the plurality of dielectric layers may be formed of, for example, silicon oxide, borophosphosilicate glass, undoped silicate glass, fluorinated silicate glass, low-k dielectric materials, the like, or a combination thereof. The low-k dielectric materials may have a dielectric constant less than 3.0 or even less than 2.5. In some embodiments, the low-k dielectric materials may have a dielectric constant less than 2.0. The plurality of dielectric layers may be formed by deposition processes such as chemical vapor deposition, plasma-enhanced chemical vapor deposition, or the like. Planarization processes may be performed after the deposition processes to remove excess material and provide a substantially flat surface for subsequent processing steps.

The plurality of conductive features may include interconnect layers, conductive vias, and conductive pads. The interconnect layers may be separated from each other and may be horizontally disposed in the plurality of dielectric layers along the direction Z. In the present embodiment, the topmost interconnect layers may be designated as the conductive pads. The conductive vias may connect adjacent interconnect layers along the direction Z, adjacent device element and interconnect layer, and adjacent conductive pad and interconnect layer. In some embodiments, the conductive vias may improve heat dissipation and may provide structure support. In some embodiments, the plurality of conductive features may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The plurality of conductive features may be formed during the formation of the plurality of dielectric layers.

In some embodiments, the plurality of device elements and the plurality of conductive features may together configure functional units of the substrate 111. A functional unit, in the description of the present disclosure, generally refers to functionally related circuitry that has been partitioned for functional purposes into a distinct unit. In some embodiments, the functional units of the substrate 111 may include, for example, highly complex circuits such as processor cores, memory controllers, or accelerator units.

With reference to FIG. 2, the first dielectric layer 113 may be formed on the substrate 111. In some embodiments, the first dielectric layer 113 may be part of the plurality of dielectric layers of the substrate 111. In some embodiments, the first dielectric layer 113 may be formed of, for example, silicon oxide, borophosphosilicate glass, undoped silicate glass, fluorinated silicate glass, low-k dielectric materials such as a spin-on low-k dielectric layer or a chemical vapor deposition low-k dielectric layer, or a combination thereof. In some embodiments, the first dielectric layer 113 may include a self-planarizing material such as a spin-on glass or a spin-on low-k dielectric material such as SiLK™. The use of a self-planarizing dielectric material may avoid the need to perform a subsequent planarizing step. In some embodiments, the first dielectric layer 113 may be formed by a deposition process including, for example, chemical vapor deposition, plasma enhanced chemical vapor deposition, evaporation, or spin-on coating. In some embodiments, a planarization process, such as chemical mechanical polishing, may be performed to provide a substantially flat surface for subsequent processing steps. In the present embodiment, the first dielectric layer 113 is formed of silicon oxide. In some embodiments, the first dielectric layer 113 may consist essentially of silicon oxide.

It should be noted that, in the description of the present disclosure, a feature which “consists essentially of” an identified material comprises greater than 95%, greater than 98%, greater than 99% or greater than 99.5% of the stated material on an atomic basis.

With reference to FIG. 2, the first mask layer 511 may be formed on the first dielectric layer 113. The first mask layer 511 may have the pattern of the first opening 513 and the second opening 515. In some embodiments, the first mask layer 511 may be a photoresist layer.

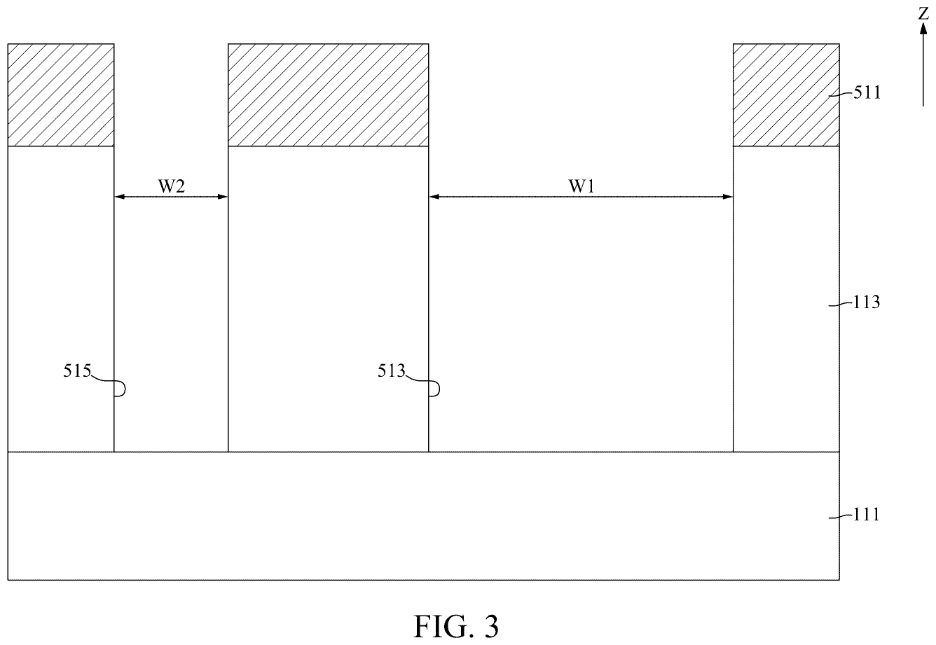

With reference to FIG. 3, an etch process, such as an anisotropic dry etch process, may be performed using the first mask layer 511 as the mask to remove portions of the first dielectric layer 113. In some embodiments, the etch rate ratio of the first dielectric layer 113 to the first mask layer 511 may be between about 100:1 and about 1.05:1, between about 15:1 and about 2:1, or between about 10:1 and about 2:1 during the etch process. In some embodiments, the etch rate ratio of the first dielectric layer 113 to the substrate 111 may be between about 100:1 and about 1.05:1, between about 15:1 and about 2:1, or between about 10:1 and about 2:1 during the etch process. After the etch process, the first opening 513 and the second opening 515 may be formed along the first dielectric layer 113. Portions of the substrate 111 may be exposed through the first opening 513 and the second opening 515. The first mask layer 511 may be removed after the first opening 513 and the second opening 515 are formed.

With reference to FIG. 3, in some embodiments, the width W1 of the first opening 513 may be greater than the width W2 of the second opening 515. In some embodiments, the width ratio of the width W1 of the first opening 513 to the width W2 of the second opening 515 may be between about 8:1 and about 3:1 or between about 6:1 and about 3:1. In some embodiments, the width W1 of the first opening 513 may be greater than about 60 nanometers (nm). In some embodiments, the width W2 of the second opening 515 may be less than 20 nm.

With reference to FIGS. 1, 4, and 5, at step S13, a first contact 210 may be formed in the first opening 513 and a second contact 220 may be formed in the second opening 515.

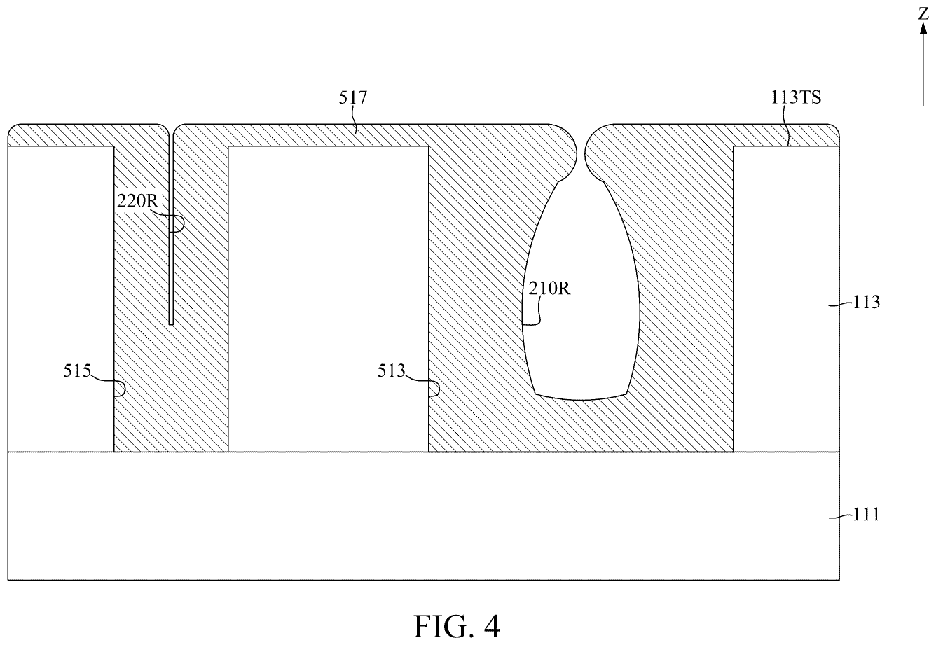

With reference to FIG. 4, the layer of conductive material 517 may be formed to partially fill the first opening 513, partially fill the second opening 515, and cover the top surface 113TS of the first dielectric layer 113. In some embodiments, the conductive material 517 may be, for example, polycrystalline silicon, polycrystalline germanium, polycrystalline silicon germanium, doped polycrystalline silicon, doped polycrystalline germanium, or doped polycrystalline silicon germanium. In some embodiments, the layer of conductive material 517 may be formed by, for example, low-pressure chemical vapor deposition, high-density-plasma chemical vapor deposition, or other applicable deposition processes.

For one example, the layer of conductive material 517 may be deposited by low-pressure chemical vapor deposition. The process pressure for depositing the layer of conductive material 517 may be between about 0.1 Torr and about 50 Torr. The reaction gas for depositing the layer of conductive material 517 may include a silicon source gas such as silane and/or a doping gas such as phosphine.

For another example, the layer of conductive material 517 may be deposited by high-density-plasma chemical vapor deposition. The high-density-plasma chemical vapor deposition may employ a plasma having an ion density on the order of 1E11 ions/cm\hat{ }3 or greater. The high-density-plasma chemical vapor deposition may also have an ionization fraction (ion/neutral ratio) on the order of 1E-4 or greater. The high-density-plasma chemical vapor deposition may include a pretreatment operation and a deposition operation.

In some embodiments, the pretreatment operation may include applying a hydrogen plasma to the first opening 513 and the second opening 515. The deposition operation may include applying a silicon-source plasma to deposit the layer of conductive material 517. A bias may be optionally applied during the deposition operation.

In some embodiments, during the pretreatment operation and the deposition operation, the substrate temperature may be below or about 500° C., below or about 450° C., or below or about 400° C. The substrate temperature may be controlled in a variety of ways. For example, the substrate temperature may be raised by a frontside plasma and may be cooled by a backside flow of helium.

In some embodiments, the hydrogen plasma may be generated using a hydrogen source. The hydrogen source may be, for example, hydrogen, ammonia, or hydrazine. In some embodiments, the silicon-source plasma may be generated using a silicon source. The silicon source may be, for example, silane, disilane, or other high order silanes.

In some embodiments, the hydrogen source and/or the silicon source may be combined with inert gases which may assist in stabilizing the high-density plasma. The inert gases may include argon, neon, and/or helium.

In some embodiments, a source of dopants may also be included during the deposition operation in order to incorporate dopants in the layer of conductive material 517. The nature of the high-density plasma allows the dopants to bond more tightly within the layer of conductive material 517 which obviates the requirement for a separate thermal dopant activation step. For one example, a boron-containing precursor (e.g., triethylborane, trimethylborane, borane, diborane, or higher order boranes) may be used as the source of dopants in order to put activated boron doping centers in the layer of conductive material 517. For another example, a phosphorus-containing precursor (e.g., phosphine) may be used as the source of dopants in order to put activated phosphorus doping centers in the layer of conductive material 517.

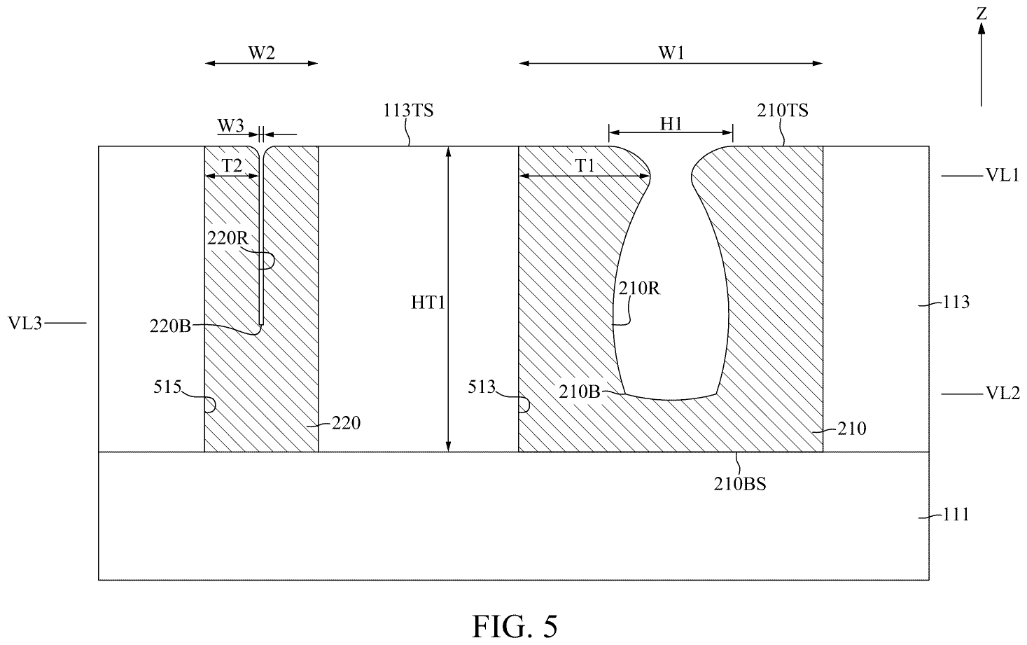

With reference to FIG. 5, a planarization process, such as chemical mechanical polishing, may be performed until the top surface 113TS of the first dielectric layer 113 is exposed to remove excess material and provide a substantially flat surface for subsequent processing steps. After the planarization process, the remaining conductive material 517 in the first opening 513 is referred to as the first contact 210 and the remaining conductive material 517 in the second opening 515 is referred to as the second contact 220.

With reference to FIG. 5, the first contact 210 may include a first recess 210R inwardly formed from the top surface 113TS of the first dielectric layer 113 toward the substrate 111. The first recess 210R may have a vase-like cross-sectional profile. The horizontal distance H1 between the sidewalls of the first recess 210R may be varied along the direction Z. For one example, initially, the horizontal distance H1 between the sidewalls of the first recess 210R may decrease until the vertical level VL1 and then gradually increase till the bottom 210B of the first recess 210R (e.g., the vertical level VL2). For another example, the horizontal distance H1 between the sidewalls of the first recess 210R may turn to decrease before reaching the bottom 210B of the first recess 210R.

In some embodiments, the vertical level VL1 is at between about 50% and about 90% of the height HT1 of the first contact 210. The 100% of the height HT1 of the first contact 210 is defined at the top surface 210TS of the first contact 210 and the 0% of the height HT1 of the first contact 210 is defined at the bottom surface 210BS of the first contact 210.

In some embodiments, the horizontal distance H1 between the sidewalls of the first recess 210R at the top surface 210TS of the first contact 210 and at the vertical level VL2 may be substantially the same. In some embodiments, the horizontal distance H1 between the sidewalls of the first recess 210R at the top surface 210TS of the first contact 210 and at the vertical level VL2 may be different. For example, the horizontal distance H1 between the sidewalls of the first recess 210R at the top surface 210TS of the first contact 210 may be less than the horizontal distance H1 between the sidewalls of the first recess 210R at the vertical level VL2. For another example, the horizontal distance H1 between the sidewalls of the first recess 210R at the top surface 210TS of the first contact 210 may be greater than the horizontal distance H1 between the sidewalls of the first recess 210R at the vertical level VL2.

With reference to FIG. 5, state differently, the thickness of the first contact 210 may be varied along the direction Z. The thickness T1 of the first contact 210 is defined by the horizontal distance between the first dielectric layer 113 and the adjacent sidewall of the first recess 210R. For one example, initially, the thickness T1 of the first contact 210 may increase until the vertical level VL1 and then gradually decrease till the bottom 210B of the first recess 210R (e.g., the vertical level VL2). For another example, the thickness T1 of the first contact 210 may turn to increase before reaching the bottom 210B of the first recess 210R.

With reference to FIG. 5, the second contact 220 may include a second recess 220R. Due to the small width of the second opening 515 compared to that of the first opening 513. The second opening 515 may be completely filled by the second contact 220 so that the second recess 220R may be smaller than the first recess 210R. In some embodiments, the second recess 220R may be referred to a seam (or a crack) of the second contact 220. In some embodiments, the width W3 of the second recess 220R may be less than the horizontal distance H1 between the sidewalls of the first recess 210R at the top surface 210TS of the first contact 210. In some embodiments, the bottom 220B of the second recess 220R may be at the vertical level VL3 between the vertical level VL2 of the bottom 210B of the first contact 210 and the vertical level VL1. In some embodiments, the bottom 220B of the second recess 220R may be at the vertical level VL3 higher than the vertical level VL1.

With reference to FIG. 5, in some embodiments, the width W1 of the first contact 210 may be greater than two times the thickness T1 of the first contact 210. In some embodiments, the width W2 of the second contact 220 may be less than or substantially the same as two times the thickness T2 of the second contact 220. The thickness T2 of the second contact 220 is defined by the horizontal distance between the first dielectric layer 113 and the adjacent sidewall of the second recess 220R.

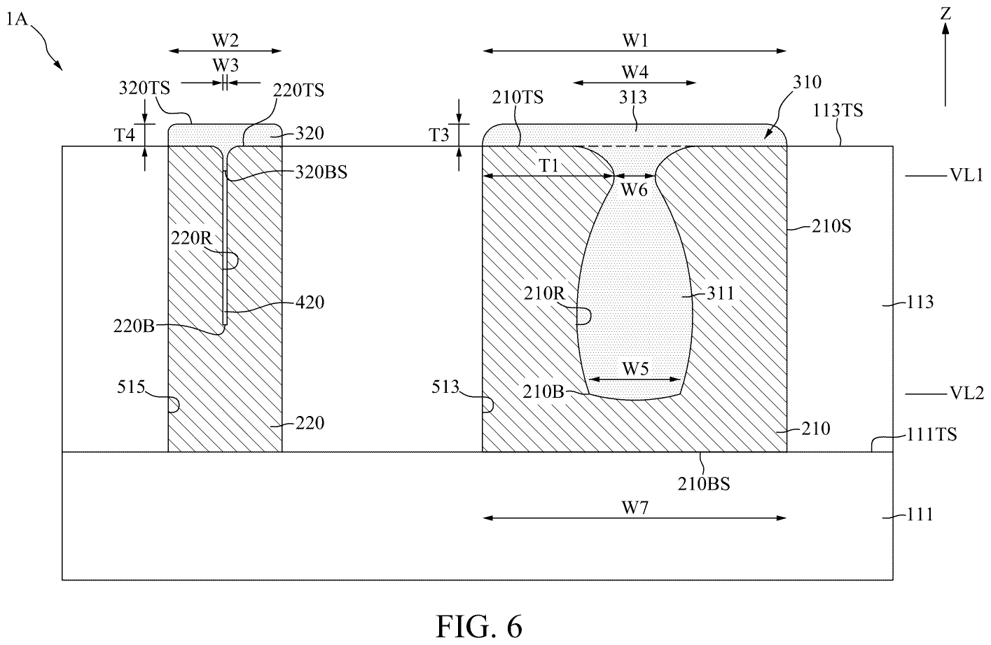

With reference to FIGS. 1 and 6, at step S15, a first assistance feature 310 may be formed on the first contact 210 and a second assistance feature 320 may be formed on the second contact 220.

With reference to FIG. 6, the first assistance feature 310 and the second assistance feature 320 may be selectively deposited on the first contact 210 and the second contact 220 over the first dielectric layer 113. In some embodiments, the first assistance feature 310 and the second assistance feature 320 may be formed of, for example, germanium. In some embodiments, the first assistance feature 310 and the second assistance feature 320 may include an atomic percentage of germanium greater than or equal to 50%. In this regard, the first assistance feature 310 and the second assistance feature 320 may be described as “germanium-rich layers”. In some embodiments, the atomic percentage of germanium in the first assistance feature 310 and the second assistance feature 320 may be greater than or equal to 60%, greater than or equal to 70%, greater than or equal to 80% greater than or equal to 90%, greater than or equal to 95%, greater than or equal to 98%, greater than or equal to 99% or greater than or equal to 99.5%. Stated differently, in some embodiments, the first assistance feature 310 and the second assistance feature 320 consists essentially of germanium. In some embodiments, the first assistance feature 310 and the second assistance feature 320 may include silicon and germanium. Stated differently, in some embodiments, the first assistance feature 310 and the second assistance feature 320 may include silicon germanium.

In some embodiments, the first assistance feature 310 and the second assistance feature 320 may be formed by a deposition process. In some embodiments, the deposition process may include a reactive gas including a germanium precursor and/or hydrogen gas. In some embodiments, the germanium precursor may consist essentially of germane. In some embodiments, the germanium precursor may include one or more of germane, digermane, isobutylgermane, chlorogermane, or dichlorogermane. In some embodiments, the hydrogen gas may be used as a carrier or diluent for the germanium precursor. In some embodiments, the reactive gas may consist essentially of germane and hydrogen gas. In some embodiments, the molar percentage of germane in the reactive gas may be in a range of about 1% to about 50%, in a range of about 2% to about 30%, or in a range of about 5% to about 20%.

Alternatively, in some embodiments, the reactive gas may further include a silicon containing precursor. In some embodiments, the silicon containing precursor may include one or more of silane, a polysilane, or a halosilane. As used in this regard, a “polysilane” is a species with the general formula SiₙH₂ₙ₊₂ where n is 2 to 6. Further, a “halosilane” is a species with the general formula SiₐX_{b}H_{2a+2-b} where X is a halogen, a is 1 to 6, and b is 1 to 2a+2. In some embodiments, the silicon containing precursor comprises one or more of SiH₄, Si₂H₆, Si₃H₈, Si₄H₁₀, SiCl₄, or SiH₂Cl₂.

In some embodiments, the temperature of the intermediate semiconductor device to be deposited may be maintained during the deposition process. The temperature may be referred to as the substrate temperature. In some embodiments, the substrate temperature may be in a range between about 300° C. and about 800° C., between about 400° C. and about 800° C., between about 500° C. and about 800° C., between about 250° C. and about 600° C., between about 400° C. and about 600° C., or between about 500° C. and about 600° C. In some embodiments, the substrate temperature may be about 540° C.

In some embodiments, the pressure of the processing chamber for depositing the first assistance feature 310 and the second assistance feature 320 may be maintained during the deposition process. In some embodiments, the pressure is maintained in a range between about 1 Torr and about 300 Torr, between about 10 Torr and about 300 Torr, between about 50 Torr and about 300 Torr, between about 100 Torr and 300 Torr, between about 200 Torr and about 300 Torr, or between about 1 Torr and about 20 Torr. In some embodiments, the pressure may be maintained at about 13 Torr.

In some embodiments, the selectivity of the deposition may be greater than or equal to 5, greater than or equal to 10, greater than or equal to 20, greater than or equal to 30, or greater than or equal to 50. In some embodiments, the first assistance feature 310 and the second assistance feature 320 may be deposited on the first contact 210 and the second contact 220 to a thickness before deposition is observed on the first dielectric layer 113.

It should be noted that, in the description of the present disclosure, the term “selectively depositing a layer on a first feature over a second feature”, and the like, means that a first amount of the layer is deposited on the first feature and a second amount of the layer is deposited on the second feature, where the first amount of the layer is greater than the second amount of the layer, or no layer is deposited on the second feature. The selectivity of a deposition process may be expressed as a multiple of growth rate. For example, if one surface is deposited on twenty-five times faster than a different surface, the process would be described as having a selectivity of 25:1 or simply 25. In this regard, higher ratios indicate more selective deposition processes.

The term “over” used in this regard does not imply a physical orientation of one feature on top of another feature, rather a relationship of the thermodynamic or kinetic properties of the chemical reaction with one feature relative to the other feature. For example, selectively depositing a germanium layer onto a silicon surface over a dielectric surface means that the germanium layer deposits on the silicon surface and less or no germanium layer deposits on the dielectric surface; or that the formation of a germanium layer on the silicon surface is thermodynamically or kinetically favorable relative to the formation of a germanium layer on the dielectric surface.

With reference to FIG. 6, the first assistance feature 310 may completely fill the first recess 210R and may be formed on the top surface 210TS of the first contact 210. Detailedly, the first assistance feature 310 may include a bottom portion 311 and a capping portion 313. The bottom portion 311 may be formed to completely fill the first recess 210R. The shape of the bottom portion 311 is determined by the first recess 210R. In other words, the bottom portion 311 may have a vase-like cross-sectional profile. The width of the bottom portion 311 may be varied along the direction Z. In one example, initially, the width of the bottom portion 311 may decrease until the vertical level VL1 and then gradually increase till the bottom 210B of the bottom portion 311 (e.g., the vertical level VL2). In some embodiments, the width of the bottom portion 311 may turn to decrease before reaching the bottom 210B of the bottom portion 311.

In some embodiments, the width of the bottom portion 311 at the top surface 210TS of the first contact 210 (also referred to as the width W4 of the bottom portion 311) and at the vertical level VL2 (also referred to as the width W5 of the bottom portion 311) may be substantially the same. In some embodiments, the width W4 of the bottom portion 311 (at the top surface 210TS of the first contact 210) and the width W5 of the bottom portion 311 (at the vertical level VL2) may be different. For example, the width W4 of the bottom portion 311 may be less than the width W5 of the bottom portion 311. For another example, the width W4 of the bottom portion 311 may be greater than the width W5 of the bottom portion 311. In some embodiments, the width of the bottom portion 311 at the vertical level VL1 (also referred to as the width W6 of the bottom portion 311) may be less than the width W5 of the bottom portion 311.

In some embodiments, the difference between the width W7 of the bottom surface 210BS of the first contact 210 and the width W5 of the bottom portion 311 may be less than two times the thickness T1 of the first contact 210. It should be noted that, in the present embodiment, the width W7 of the bottom surface 210BS of the first contact 210 and the width W1 (of the top surface 210TS) of the first contact 210 may be substantially the same. In other words, the sidewalls 210S of the first contact 210 may be substantially vertical. It should be noted that, in the description of the present disclosure, a surface is “substantially vertical” if there exists a vertical plane from which the surface does not deviate by more than three times the root mean square roughness of the surface.

With reference to FIG. 6, the capping portion 313 may be formed on the top surface 210TS of the first contact 210 and on the bottom portion 311. In some embodiments, the width of the capping portion 313 may be the same as the width W1 of the first contact 210. In some embodiments, the width of the capping portion 313 may be slightly greater than the width W1 of the first contact 210.

With reference to FIG. 6, the second assistance feature 320 may be formed on the second contact 220. A portion of the second assistance feature 320 may downwardly extend to the second recess 220R. In other words, the bottom surface 320BS of the second assistance feature 320 may be at the vertical level VL4 lower than the top surface 210TS of the first contact 210 (i.e., the top surface 113TS of the first dielectric layer 113). The second recess 220R may be sealed by the second assistance feature 320. The space enclosed by the second assistance feature 320 and the second contact 220 may be referred to as an air gap 420.

In some embodiments, the width of the second assistance feature 320 may be the same as the width W2 of the second contact 220. In some embodiments, the width of the second assistance feature 320 may be slightly greater than the width W2 of the second assistance feature 320.

With reference to FIG. 6, the thickness T3 of the capping portion 313 and the thickness T4 of the second assistance feature 320 may be substantially the same. The thickness T4 of the second assistance feature 320 may be defined as the vertical distance from the top surface 220TS of the second contact 220 to the top surface 320TS of the second assistance feature 320.

By employing the first assistance feature 310 and the second assistance feature 320, the contact resistance of the first contact 210 and the second contact 220 may be reduced. As a result, the performance of the semiconductor device 1A may be improved.

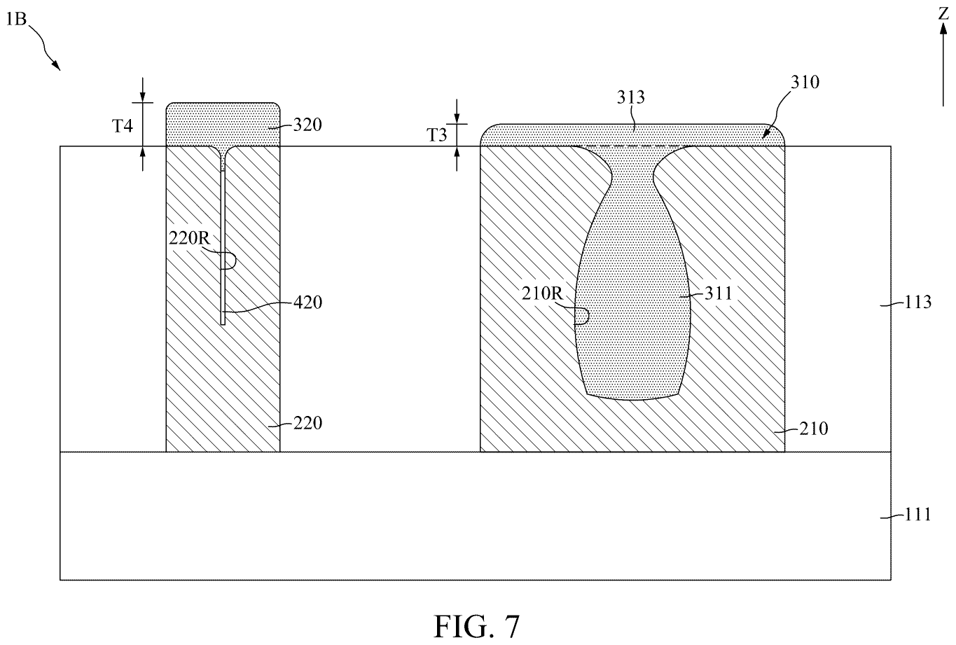

FIGS. 7 to 13 illustrate, in schematic cross-sectional view diagrams, semiconductor devices 1B, 1C, 1D, 1E, 1F, 1G, and 1H in accordance with some embodiments of the present disclosure.

With reference to FIG. 7, the semiconductor device 1B may have a structure similar to that illustrated in FIG. 6. The same or similar elements in FIG. 7 as in FIG. 6 have been marked with similar reference numbers and duplicative descriptions have been omitted. In the semiconductor device 1B, the thickness T4 of the second assistance feature 320 may be greater than the thickness T3 of the capping portion 313 of the first assistance feature 310.

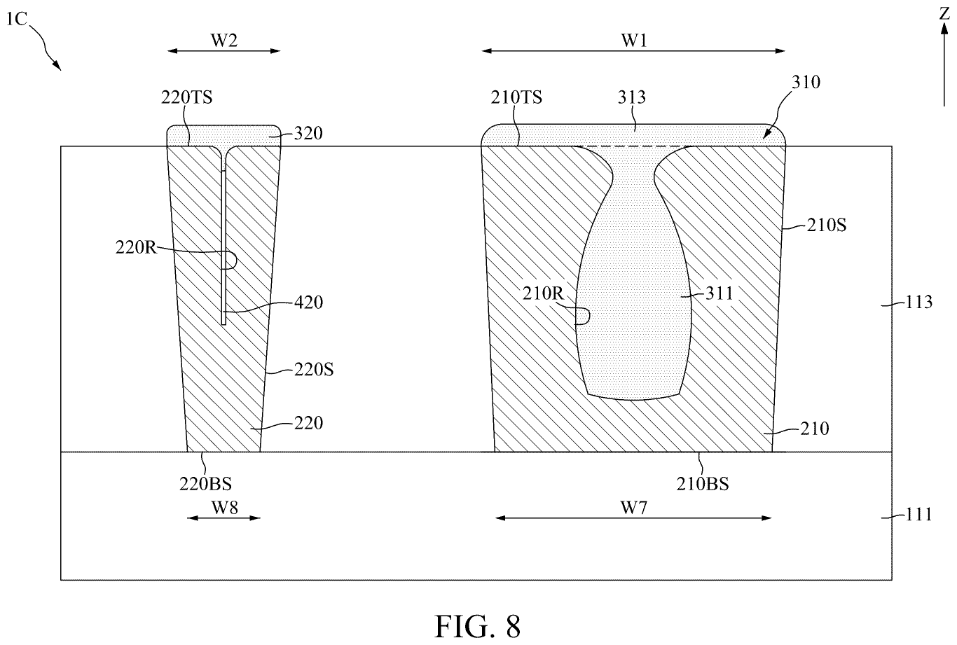

With reference to FIG. 8, the semiconductor device 1C may have a structure similar to that illustrated in FIG. 6. The same or similar elements in FIG. 8 as in FIG. 6 have been marked with similar reference numbers and duplicative descriptions have been omitted. In the semiconductor device 1C, the sidewalls 210S of the first contact 210 and the sidewalls 220S of the second contact 220 may be tapered. In some embodiments, the width W1 of the top surface 210TS of the first contact 210 may be greater than the width W7 of the bottom surface 210BS of the first contact 210. In some embodiments, the width W2 of the top surface 220TS of the second contact 220 may be greater than the width W8 of the bottom surface 220BS of the second contact 220.

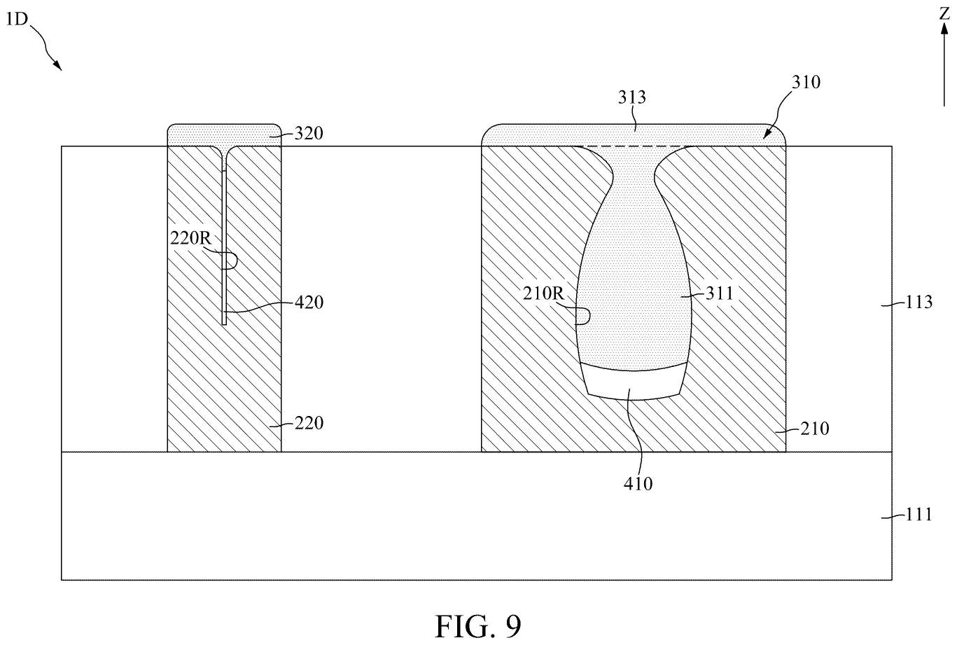

With reference to FIG. 9, the semiconductor device 1D may have a structure similar to that illustrated in FIG. 6. The same or similar elements in FIG. 9 as in FIG. 6 have been marked with similar reference numbers and duplicative descriptions have been omitted. In the semiconductor device 1D, the bottom portion 311 of the first assistance feature 310 may not completely fill the first recess 210R. The space enclosed by the bottom portion 311 and the first contact 210 may be referred to as an air gap 410.

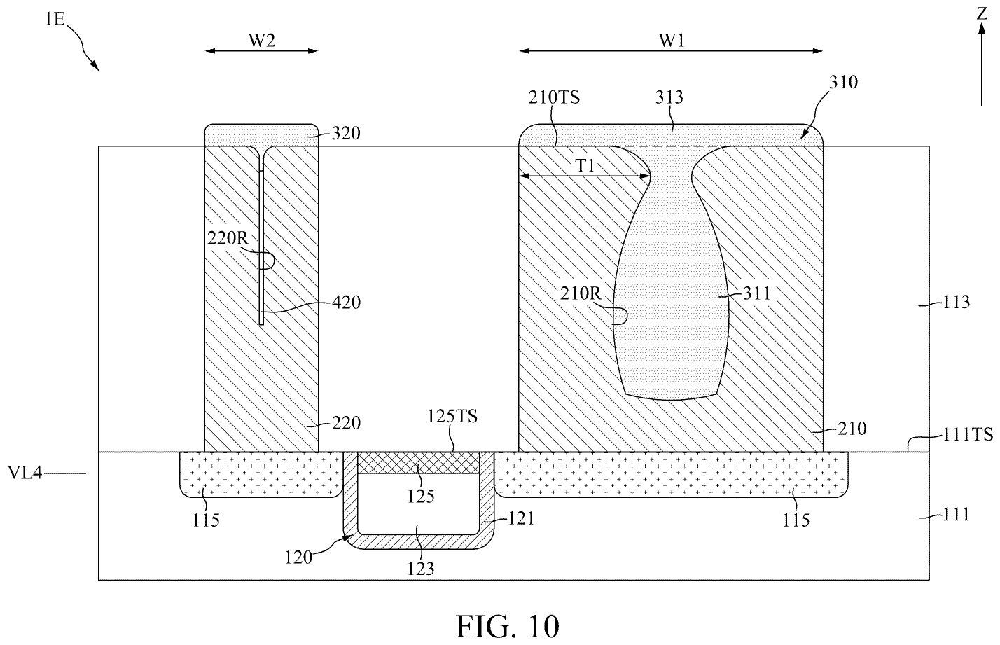

With reference to FIG. 10, the semiconductor device 1E may have a structure similar to that illustrated in FIG. 6. The same or similar elements in FIG. 10 as in FIG. 6 have been marked with similar reference numbers and duplicative descriptions have been omitted. The semiconductor device 1E may include a plurality of impurity regions 115 and a word line structure 120.

With reference to FIG. 10, the plurality of impurity regions 115 may be disposed in the substrate 111 and separated from each other. The first contact 210 and the second contact 220 may be disposed on the plurality of impurity regions 115, respectively and correspondingly.

The plurality of impurity regions 115 may be doped with p-type dopants or n-type dopants. The p-type dopants may create deficiencies of valence electrons. In a silicon-containing substrate, examples of p-type dopants may include but are not limited to boron, aluminum, gallium, or indium. The n-type dopants may contribute free electrons to the intrinsic semiconductor. In a silicon-containing substrate, examples of n-type dopants may include but are not limited to antimony, arsenic, and phosphorus. In some embodiments, the dopant concentration of the plurality of impurity regions 115 may be between about 1E19 atoms/cm\hat{ }3 and about 1E21 atoms/cm\hat{ }3.

With reference to FIG. 10, the word line structure 120 may be disposed in the substrate 111 and between the plurality of impurity regions 115. The word line structure 120 may include a word line dielectric layer 121, a word line conductive layer 123, and word line capping layer 125.

With reference to FIG. 10, the word line dielectric layer 121 may be inwardly disposed in the substrate 111. The word line dielectric layer 121 may have a U-shaped cross-sectional profile. In some embodiments, the word line dielectric layer 121 may include a high-k material, an oxide, a nitride, an oxynitride or combinations thereof. In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

With reference to FIG. 10, the word line conductive layer 123 may be disposed on the word line dielectric layer 121. The top surface of the word line conductive layer 123 may be at the vertical level VL4 lower than the top surface 111TS of the substrate 111. In some embodiments, the word line conductive layer 123 may be formed of, for example, doped polycrystalline silicon, doped polycrystalline germanium, doped polycrystalline silicon germanium, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

With reference to FIG. 10, the word line capping layer 125 may be disposed on the word line conductive layer 123. The top surface 125TS of the word line capping layer 125 and the top surface 111TS of the substrate 111 may be substantially coplanar. In some embodiments, the word line capping layer 125 may be formed of, for example, silicon oxide, silicon nitride, silicon oxynitride, silicon nitride oxide, or other applicable dielectric material.

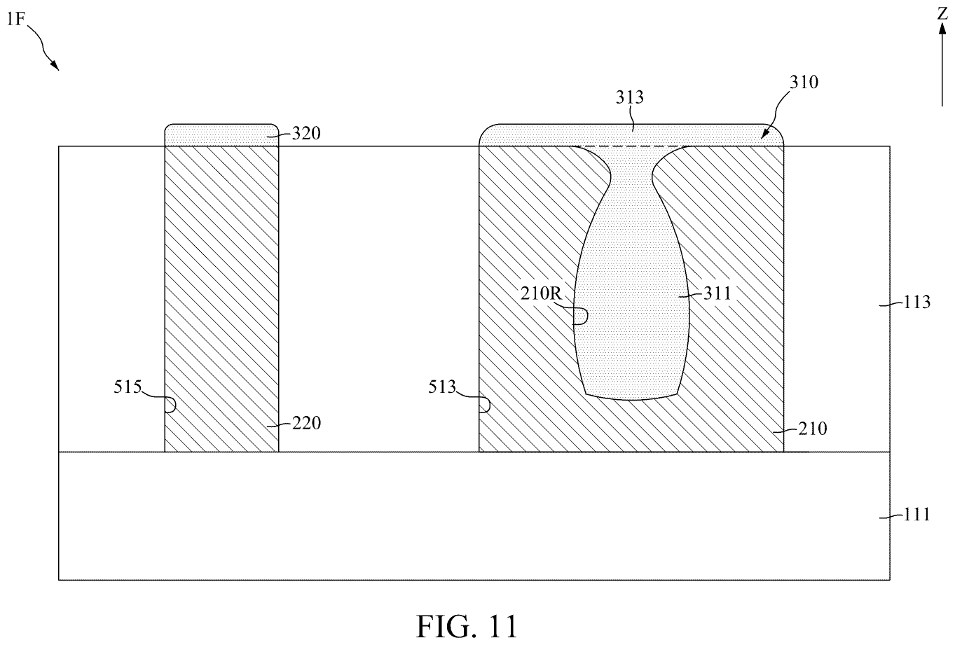

With reference to FIG. 11, the semiconductor device 1F may have a structure similar to that illustrated in FIG. 6. The same or similar elements in FIG. 11 as in FIG. 6 have been marked with similar reference numbers and duplicative descriptions have been omitted. In the semiconductor device 1F, the second contact 220 may completely fill the second opening 515. That is, no recesses, air gaps, seams, or cracks are present in the second contact 220.

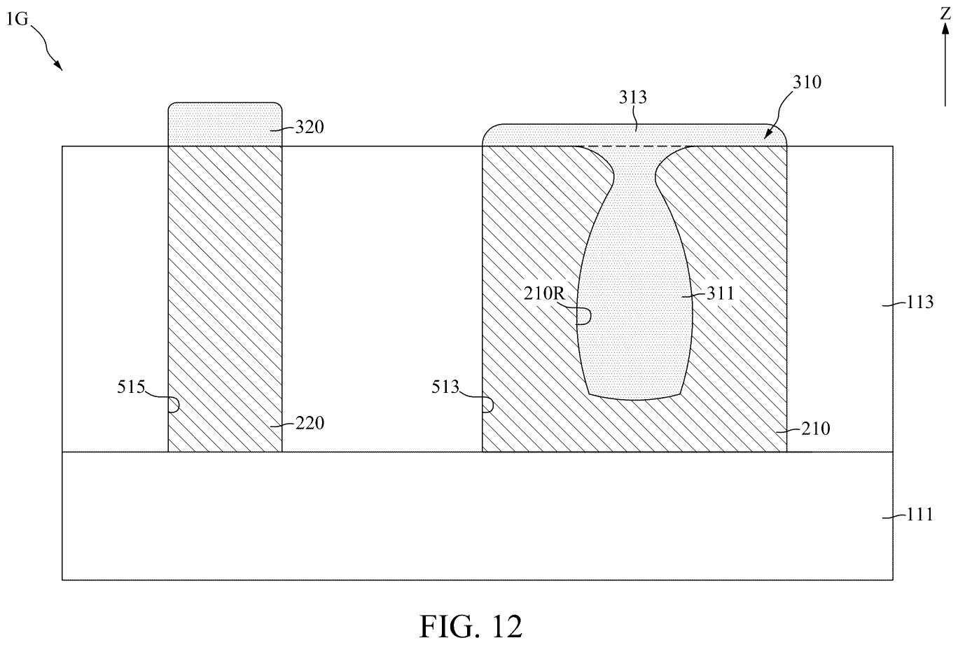

With reference to FIG. 12, the semiconductor device 1G may have a structure similar to that illustrated in FIG. 7. The same or similar elements in FIG. 12 as in FIG. 7 have been marked with similar reference numbers and duplicative descriptions have been omitted. In the semiconductor device 1G, the second contact 220 may completely fill the second opening 515. That is, no recesses, air gaps, seams, or cracks are present in the second contact 220.

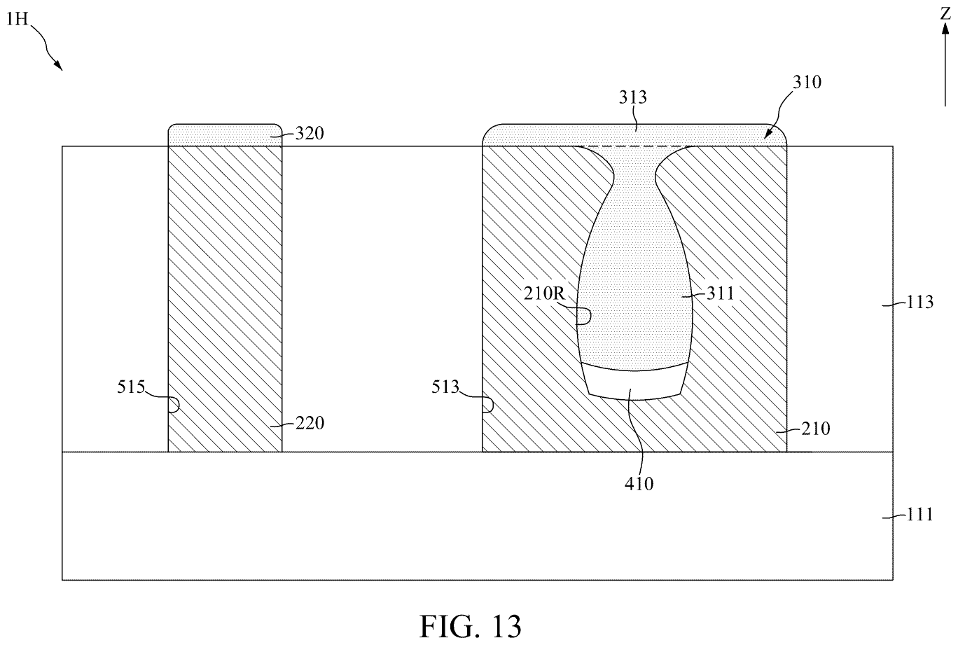

With reference to FIG. 13, the semiconductor device 1H may have a structure similar to that illustrated in FIG. 9. The same or similar elements in FIG. 13 as in FIG. 9 have been marked with similar reference numbers and duplicative descriptions have been omitted. In the semiconductor device 1H, the second contact 220 may completely fill the second opening 515. That is, no recesses, air gaps, seams, or cracks are present in the second contact 220.

One aspect of the present disclosure provides a semiconductor device including a substrate; a first contact positioned on the substrate; a first assistance feature including: a bottom portion positioned in the first contact, and a capping portion positioned on the bottom portion and on a top surface of the first contact; a second contact positioned on the substrate and separated from the first contact; and a second assistance feature positioned on the second contact. The first assistance feature and the second assistance feature include germanium or silicon germanium.

Another aspect of the present disclosure provides a semiconductor device including a substrate; a plurality of impurity regions positioned in the substrate and separated from each other; a word line structure positioned between the plurality of impurity regions and positioned in the substrate; a first contact and a second contact respectively and correspondingly positioned on the plurality of impurity regions; and a first assistance feature including: a bottom portion positioned in the first contact, and a capping portion positioned on the bottom portion and on a top surface of the first contact. The first assistance feature and the second assistance feature include germanium or silicon germanium.

Another aspect of the present disclosure provides a method for fabricating a semiconductor device including providing a substrate; forming a first dielectric layer on the substrate; forming a first opening and a second opening along the first dielectric layer; forming a layer of conductive material to partially fill the first opening, fill the second opening, and cover a top surface of the first dielectric layer; performing a planarization process until the top surface of the first dielectric layer is exposed to turn the layer of conductive material into a first contact in the first opening and a second contact in the second opening; and forming a first assistance feature on the first contact and forming a second assistance feature on the second contact. The first assistance feature and the second assistance feature include germanium or silicon germanium.

Due to the design of the semiconductor device of the present disclosure, the contact resistance of the first contact 210 and the second contact 220 may be reduced by employing the first assistance feature 310 and the second assistance feature 320. As a result, the performance of the semiconductor device 1A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for fabricating a semiconductor device, comprising:
providing a substrate;
forming a first dielectric layer on the substrate;
forming a first opening and a second opening along the first dielectric layer;
forming a layer of conductive material to partially fill the first opening, fill the second opening, and cover a top surface of the first dielectric layer;
performing a planarization process until the top surface of the first dielectric layer is exposed to turn the layer of conductive material into a first contact in the first opening and a second contact in the second opening; and
forming a first assistance feature on the first contact and forming a second assistance feature on the second contact;
wherein the first assistance feature and the second assistance feature comprise germanium or silicon germanium.

2. The method for fabricating the semiconductor device of claim 1, wherein the first contact and the second contact comprise silicon and/or germanium with substantially no oxygen and nitrogen.

3. The method for fabricating the semiconductor device of claim 1, wherein the conductive material comprises polycrystalline silicon, polycrystalline germanium, or polycrystalline silicon germanium.

4. The method for fabricating the semiconductor device of claim 1, wherein the layer of conductive material is doped with n-type dopants or p-type dopants.

5. The method for fabricating the semiconductor device of claim 1, wherein the layer of conductive material is doped with p-type dopants.

6. The method for fabricating the semiconductor device of claim 1, wherein the layer of conductive material is formed by low-pressure chemical vapor deposition.

7. The method for fabricating the semiconductor device of claim 1, wherein a process temperature of forming the first assistance feature and the second assistance feature is between about 300° C. and about 800° C.

8. The method for fabricating the semiconductor device of claim 7, wherein a process pressure of forming the first assistance feature and the second assistance feature is between about 1 Torr and about 300 Torr.

9. The method for fabricating the semiconductor device of claim 8, wherein a reactive gas of forming the first assistance feature and the second assistance feature comprises a germanium precursor and/or hydrogen gas.

10. The method for fabricating the semiconductor device of claim 9, wherein the germanium precursor comprises germane, digermane, isobutylgermane, chlorogermane, or dichlorogermane.
